(19) United States
(12) Patent Application Publication
(10) Pub. No.: US 2017/0335603 A1
(43) Pub. Date: Nov. 23, 2017

(54) GUARANTEED CLOSED SAFETY LOCK

(71) Applicant: CommScope Connectivity Belgium BVBA, Kessel-Lo (BE)

(72) Inventors: Roger ALAERTS, Aarschot (BE); Eric SCHURMANS, Geetbets (BE)

(73) Assignee: CommScope Connectivity Belgium BVBA, Kessel-Lo (BE)

(21) Appl. No.: 15/523,168

(22) PCT Filed: Oct. 29, 2015
(86) PCT No.: PCT/EP2015/075192

§ 371 Date: Apr. 28, 2017

Related U.S. Application Data
(60) Provisional application No. 62/073,631, filed on Oct. 31, 2014.

(51) Int. Cl. E05B 65/00; H05K 5/02; E05C 3/02; E05B 63/18; E05B 35/00; H05K 5/03; E05B 11/00

(52) U.S. Cl. CPC E05B 65/006; H05K 5/03; H05K 5/0221; E05B 11/00; E05B 63/185; E05B 35/008; E05C 3/02

(57) ABSTRACT

Telecommunications enclosures (10, 110) and related methods are disclosed. In one aspect, the enclosure (10) includes a base (20), a cover (40), a lock assembly (70) for securing the base (20) to the cover (40), and a key (60) for operating the lock assembly (70). In one aspect, a lock clip (80) of the lock assembly (70) enables operation of the lock assembly (70) when the cover (40) is in the closed position. In another aspect, the lock clip (80) disables operation of the lock assembly (70) when the cover (40) is in the open position such that the lock assembly (70) is prevented from being operated out of the open position. In yet another aspect, the key (60) is prevented from being removed from the cover (40) when the key (60) operates the lock assembly (70) out of the locked position.

### CROSS-REFERENCE TO RELATED APPLICATION

This application claims the benefit of U.S. Patent Application Ser. No. 62/073,631, filed on Oct. 31, 2014, the disclosure of which is incorporated herein by reference in its entirety.

### FIELD OF THE INVENTION

The present invention relates to systems and methods for locking telecommunications enclosures.

### BACKGROUND

Enclosures are known for managing telecommunications cables and connectivity equipment, including splices, splitters, wave division multiplexers and termination. The enclosures may be mounted outside and include movable covers for accessing an interior of the enclosures. There is a need for maintaining the covers in the closed position. There is also a need for providing limited access to the interiors, such as with a security feature.

### SUMMARY

A telecommunications enclosure is disclosed having a cover, a base, a lock assembly, and a key for operating the lock assembly. The disclosed combination of features results in an enclosure in which the key can only rotate the lock assembly to a locked position when the cover is fully closed and in which the key can only be axially removed from the cover when the lock assembly is in the locked position. In one example, a portion of the base axially engages with the lock assembly only when the cover is fully closed relative to the base. This engagement enables the lock assembly to be moved out of the unlocked position and towards the locked position by operation of the key. This configuration prevents an operator from axially removing the key when the cover may not be fully closed and/or unlocked and ensures that the cover is fully closed and locked to the base before removal of the key is allowed.

In one aspect of the disclosure, a method for servicing a telecommunications enclosure is provided. The method can include the steps of: providing a telecommunications enclosure having a base and a cover that can be secured together with a lock assembly operable by a key; axially inserting the key into the lock assembly; rotating the key to axially engage the key to the cover and to rotate a lock member to an unlocked position such that the cover can be opened with respect to the base; and disabling the operation of the lock assembly such that the lock assembly cannot be moved out of the unlocked position by opening the cover to axially disengage the lock assembly from a portion of the base. The method can also include the steps of: enabling the operation of the lock assembly such that the lock assembly can be moved out of the unlocked position by closing the cover such that the lock assembly axially engages with the portion of the base; rotating the key to axially disengage the key from the cover and to rotate the lock member to a locked position such that the cover cannot be opened with respect to the base; and axially removing the key from the lock assembly.

In one example, the cover can be movable between open and closed positions relative to the base. In one aspect, the base includes a lock engagement feature and a lock activation feature. In another aspect, the cover includes a key engagement feature. The telecommunications enclosure can also include a lock assembly including a lock member for locking the cover to the base via engagement with the lock engagement feature. The lock assembly can also include a lock clip for enabling and disabling operation of the lock assembly. A key may also be provided to operate the lock assembly. In one example, the key includes a cover engagement structure.

In one aspect, the lock clip enables operation of the lock assembly when the cover is in the closed position, wherein the lock clip is engaged with the lock activation feature when the cover is in the closed position. In another aspect, the lock clip disables operation of the lock assembly when the cover is in the open position such that the lock assembly is prevented from being operated out of the open position. In yet another aspect, the key engagement feature engages with the cover engagement structure to secure the key to the cover when the key operates the lock assembly out of the locked position.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 is a perspective view of an example telecommunications enclosure having a lock assembly in accordance with principles of the present disclosure;

FIG. 2 is a perspective view of a portion of the telecommunications enclosure of FIG. 1;

FIG. 3 is a perspective view of a key usable for locking and unlocking a lock assembly associated with the telecommunications enclosure of FIG. 1;

FIG. 4 is a perspective view of a portion of the telecommunications enclosure of FIG. 1, with the key removed;

FIG. 5 is a perspective view of a portion of the telecommunications enclosure of FIG. 1;

FIG. 6 is a perspective view of a lock core associated with the lock assembly of the telecommunications enclosure of FIG. 1;

FIG. 7 is a perspective view of the lock core of FIG. 6;

FIG. 8 is a perspective view of a cap associated with the lock assembly of the telecommunications enclosure of FIG. 1;

FIG. 9 is a perspective view of the cap of FIG. 8;

FIG. 10 is a perspective view of a retainer associated with the lock assembly of the telecommunications enclosure of FIG. 1;

FIG. 11 is a cross-sectional view of the lock core of FIG. 6 aligned with a lock shaft feature of the telecommunications enclosure of FIG. 1;

FIG. 12 is a cross-sectional view of the lock core of FIG. 6 inserted into the lock shaft feature of the telecommunications enclosure of FIG. 1;

FIG. 13 is a cross-sectional view of the cap of FIG. 8 aligned with the lock shaft feature of the telecommunications enclosure of FIG. 1;

FIG. 14 is a cross-sectional view of the cap of FIG. 8 inserted onto the lock shaft feature of the telecommunications enclosure of FIG. 1;

FIG. 15 is a cross-sectional view of the inserted cap and lock core onto the lock shaft feature of FIG. 1 with a retainer aligned with a groove in the lock core;

FIG. 16 is a cross-sectional view of the lock assembly of FIG. 15 with the retainer installed onto the lock core;

FIG. 17 is a cross-sectional side view of the telecommunications enclosure of FIG. 1 in an open position with the key partially inserted;

FIG. 18 is a cross-sectional view of the telecommunications enclosure of FIG. 1 in a partially open position with the key fully inserted with the lock assembly in an unlocked position;

FIG. 19 is a cross-sectional view of the telecommunications enclosure of FIG. 1 in a fully closed position with the key fully inserted with the lock assembly in an unlocked position;

FIG. 20 is an enlarged portion of the cross-sectional side view of the telecommunications enclosure shown in FIG. 19;

FIG. 21 is a cross-sectional view of the telecommunications enclosure of FIG. 1 in a fully closed position with the key fully inserted with the lock assembly being turned towards the locked position;

FIG. 22 is a cross-sectional view of the telecommunications enclosure of FIG. 1 in a fully closed position with the key fully inserted with the lock assembly being in the locked position;

FIG. 23 is an enlarged portion of the cross-sectional side view of the telecommunications enclosure shown in FIG. 22;

FIG. 24 is a cross-sectional view of the telecommunications enclosure of FIG. 1 in a fully closed position with the partially removed with the lock assembly being in the locked position;

FIG. 25 is a perspective view of the telecommunications enclosure shown in FIG. 1.

FIG. 26 is an enlarged portion of the perspective view of the telecommunications enclosure shown in FIG. 25;

FIG. 27 is a perspective view of a second example of a telecommunications enclosure having a lock assembly in accordance with principles of the present disclosure;

FIG. 28 is a perspective view of a portion of the telecommunications enclosure of FIG. 27;

FIG. 29 is a perspective view of a portion of the telecommunications enclosure of FIG. 27;

FIG. 30 is a perspective view of a portion of the telecommunications enclosure of FIG. 27;

FIG. 31 is a perspective view of a lock core associated with the lock assembly of the telecommunications enclosure of FIG. 27;

FIG. 32 is a perspective view of the lock core of FIG. 31;

FIG. 33 is a perspective view of a rotation disk associated with the lock assembly of the telecommunications enclosure of FIG. 27;

FIG. 34 is a perspective view of a retainer associated with the lock assembly of the telecommunications enclosure of FIG. 27;

FIG. 35 is a perspective view of a cap associated with the lock assembly of the telecommunications enclosure of FIG. 27;

FIG. 36 is a cross-sectional view of the lock core of FIG. 31 aligned with a lock shaft feature of the telecommunications enclosure of FIG. 27;

FIG. 37 is a cross-sectional view of the lock core of FIG. 31 inserted into the lock shaft feature of the telecommunications enclosure of FIG. 27;

FIG. 38 is a cross-sectional view of the cap of FIG. 35 aligned with the lock shaft feature of the telecommunications enclosure of FIG. 27;

FIG. 39 is a perspective view of the cap of FIG. 35 inserted onto the lock shaft feature of the telecommunications enclosure of FIG. 27;

FIG. 40 is a cross-sectional view of the cap of FIG. 35 inserted onto the lock shaft feature of the telecommunications enclosure of FIG. 27;

FIG. 41 is a cross-sectional view of the inserted cap and lock core onto the lock shaft feature of FIG. 27 with a rotation disk aligned with a groove in the lock core;

FIG. 42 is a cross-sectional view of the lock assembly of FIG. 41 with the rotation disk installed onto the lock core;

FIG. 43 is a cross-sectional view of the inserted cap, lock core, and rotation disk onto the lock shaft feature of FIG. 27 with a retainer aligned with a groove in the lock core;

FIG. 44 is a cross-sectional view of the lock assembly of FIG. 43 with the retainer installed onto the lock core;

FIG. 45 is a cross-sectional view of the telecommunications enclosure of FIG. 27 in an open position with the key partially inserted;

FIG. 46 is a cross-sectional view of the telecommunications enclosure of FIG. 27 in a partially open position with the key fully inserted with the lock assembly in an unlocked position;

FIG. 47 is a cross-sectional view of the telecommunications enclosure of FIG. 1 in a fully closed position with the key fully inserted with the lock assembly in an unlocked position;

FIG. 48 is an enlarged portion of the cross-sectional side view of the telecommunications enclosure shown in FIG. 47;

FIG. 49 is a cross-sectional side view of the telecommunications enclosure of FIG. 1 in a fully closed position with the lock assembly in the locked position and the key partially removed;

FIG. 50 is a perspective view of the telecommunications enclosure of FIG. 27 in a partially open position with the key fully inserted;

FIG. 51 is a perspective view of the telecommunications enclosure of FIG. 27 in a fully closed position; and

FIG. 52 is a perspective view of the telecommunications enclosure of FIG. 27 in a fully closed position with the key fully inserted.

### DETAILED DESCRIPTION

Reference will now be made in detail to exemplary aspects of the present disclosure that are illustrated in the accompanying drawings. Whenever possible, the same reference numbers will be used throughout the drawings to refer to the same or similar parts.

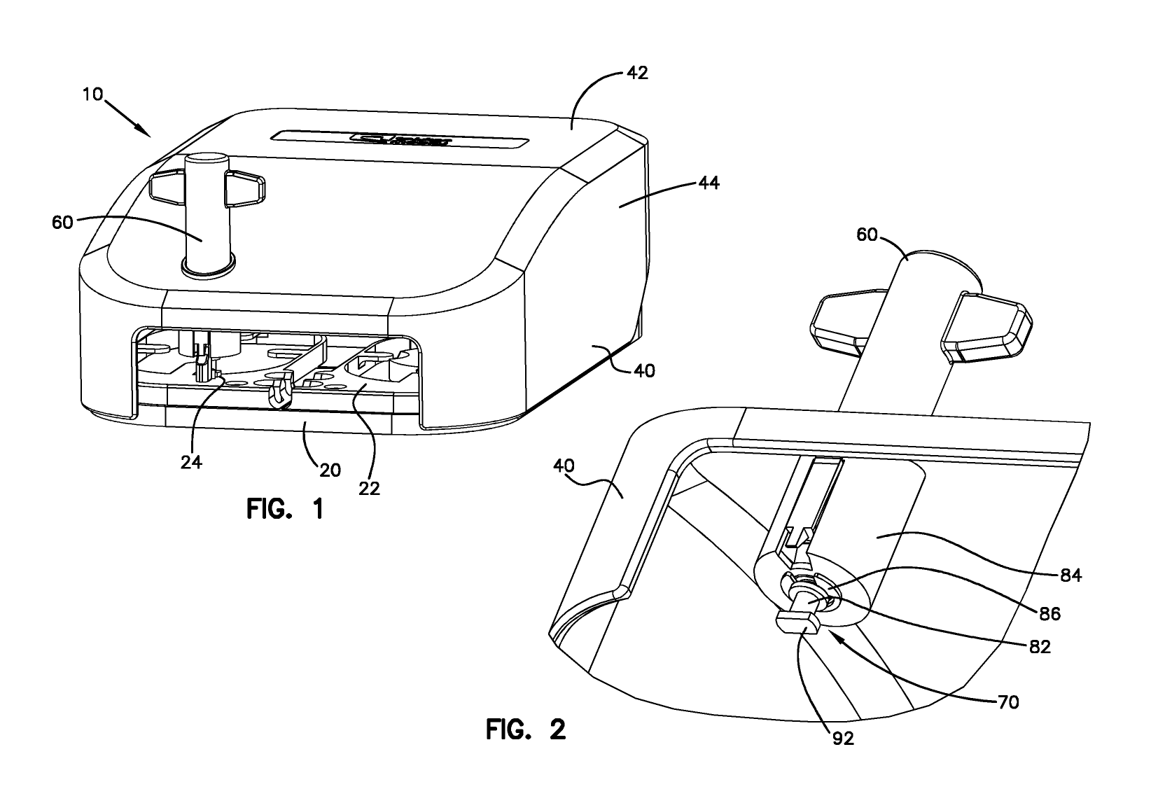

Referring to FIG. 1, a first embodiment of a telecommunications enclosure 10 is shown. Telecommunications enclosure 10 is for housing telecommunications components in an enclosed, secure environment within an interior volume 12.

As shown, telecommunications enclosure 10 includes a base 20 and a cover 40 that cooperatively define the interior volume 12. The base 20 can be configured with a mounting surface 22 to provide a support surface for mounting telecommunications components, such as telecommunications cables, connectivity equipment, splices, splitters, wave division multiplexers, and terminations. The base 20 can also be configured to include a lock engagement feature 24 for engaging with a lock assembly 70, discussed later. In the embodiment shown, the lock engagement feature 24 is configured as a latching surface 24 that is integrally molded into the base 20.

The cover 40 can be configured with a cover surface 42 and one or more sidewalls 44 to cover and protect the telecommunications components. However, the base 20 could be provided with sidewalls in addition to or instead of the cover 40 being provided with sidewalls. In one example, the cover 40 is rotatably attached to the base 20. In one example, the cover 40 is removable from the base 20.

In one aspect, the cover 40 is provided with a lock shaft feature 46 configured for receiving and engaging with a key 60 that operates the lock assembly 70, and acts as a handle for opening or removing the cover 40. The lock shaft feature 46 is also shown as being configured to support the lock assembly 70. In the embodiment shown, the lock shaft feature 46 is configured with a generally cylindrical sidewall 48, having an interior side 48a, an exterior side 48b, and an open end 48c. The open end 48c is shown as being provided with stop grooves 50 to prevent the lock assembly 70 from rotating beyond the locked position and beyond the unlocked position. The sidewall 48 may also be provided with a notch or other similar feature for engaging with a cap 84 of the lock assembly 70 to prevent rotation of the cap 84. Along the interior side 48a of the sidewall 48, an engagement structure 52 configured as a ramped protrusion is provided. The engagement structure 52 interacts with a corresponding cover engagement structure 68 of the key 60.

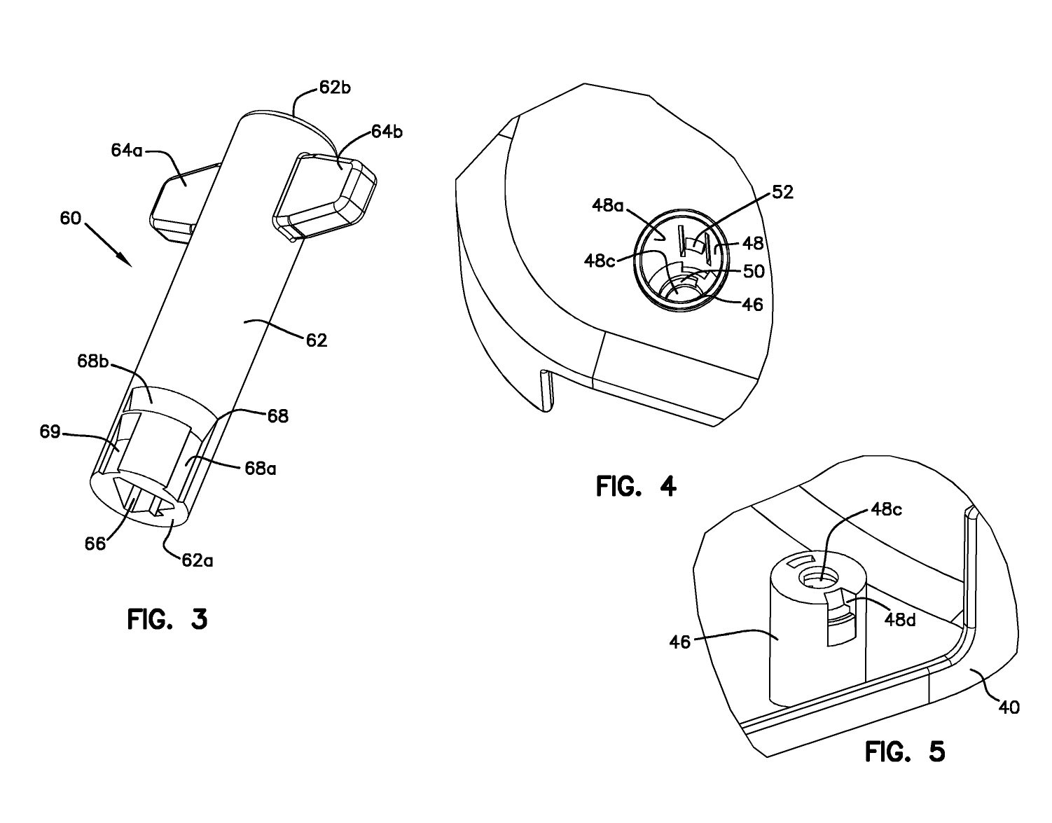

As most easily seen at FIG. 3, the key 60 is provided with a post 62 with a first end 62a and a second end 62b, and with a handle 64 having a first handle portion 64a and a second handle portion 64b. The handle portion 64 provides an operator with the means to both manually rotate the key 60 to unlock the lock assembly 70 and to pull the cover 40 open with the key 60 once the lock assembly 70 is unlocked. The key is also provided with a lock engagement structure 66, discussed later, for operating the lock assembly 70. The cover engagement feature 68 of the key 60 is shown as being provided on the post portion 62 and is configured as an L-shaped groove structure having a first portion 68a and a second portion 68b. As shown, the first portion 68a extends along the length of the post 62 from the first end 62a and towards the second end 62b of the post 62. The second portion 68b is shown as adjoining the first portion 68a and being disposed circumferentially about a portion of the post 62. As such, the first portion 68a is generally orthogonal to the second portion 68b of the cover engagement feature 68.

In use, the post 62 of the key 60 is initially inserted into the lock shaft feature 46 and is oriented such that the first portion 68a of the cover engagement structure 68 is aligned with the key engagement feature 52 of the lock shaft feature 46. When the key 60 is aligned in such a manner, the lock assembly 70 is in a locked position such that the cover 40 cannot be removed from the base 20. Once aligned, the key post 62 can be more fully inserted into the lock shaft feature 46 until the key engagement feature 52 bottoms out against the second portion 68b of the cover engagement feature 68. The location of the second portion 68b, as defined by the length of the first portion 68a, is such that the lock engagement structure 66 of the key 60 can only engage the lock assembly 70 when the key 60 has been fully inserted such that the key engagement feature 52 and the second portion 68b are aligned. Before this point, the key engagement feature 52 and the cover engagement structure 68 prevent rotation of the key 60.

Once the key post 62 has been inserted sufficiently to cause alignment between the second portion 68b and the key engagement feature 52, and when the cover 40 is fully closed, the key 60 can be rotated to operate the lock assembly 70. However, this rotation then causes the second portion 68b of the cover engagement structure 68 to engage with the key engagement feature 52 such that the key 60 is prevented from being pulled axially out of the lock shaft feature 46. In this orientation, the key 60 can act as a handle for pulling the cover 40 away from the base 20, or vice versa. It is noted that the key engagement feature 52 could be constructed as a groove or recess and the cover engagement structure 68 could be constructed as a protrusion without departing from the above described concepts.

As presented the lock assembly 70 includes a number of components, including a lock core 82, a cap 84 mounted to the lock shaft feature 46 on the cover 40, and a retainer 86, such as a circlip, that secures the lock core 82 onto the cap 84. As shown, the lock core 82 can be provided with a key engagement feature 90 and a lock member 92. The lock member 92 is configured to engage with a corresponding lock engagement feature 24 on the base 20 such that the cover 40 can be locked to the base 20 through rotation of the lock core 82. The lock engagement structure 66 of the key 60 is configured to engage with the key engagement feature 90 of the lock core 82 such that the key 60 can rotate the lock core 82. This configuration allows the key 60 to rotate the lock assembly 70 between a locked position and an unlocked position, wherein the lock member 92 is selectively engaged and disengaged with the lock engagement feature 24 on the base 20.

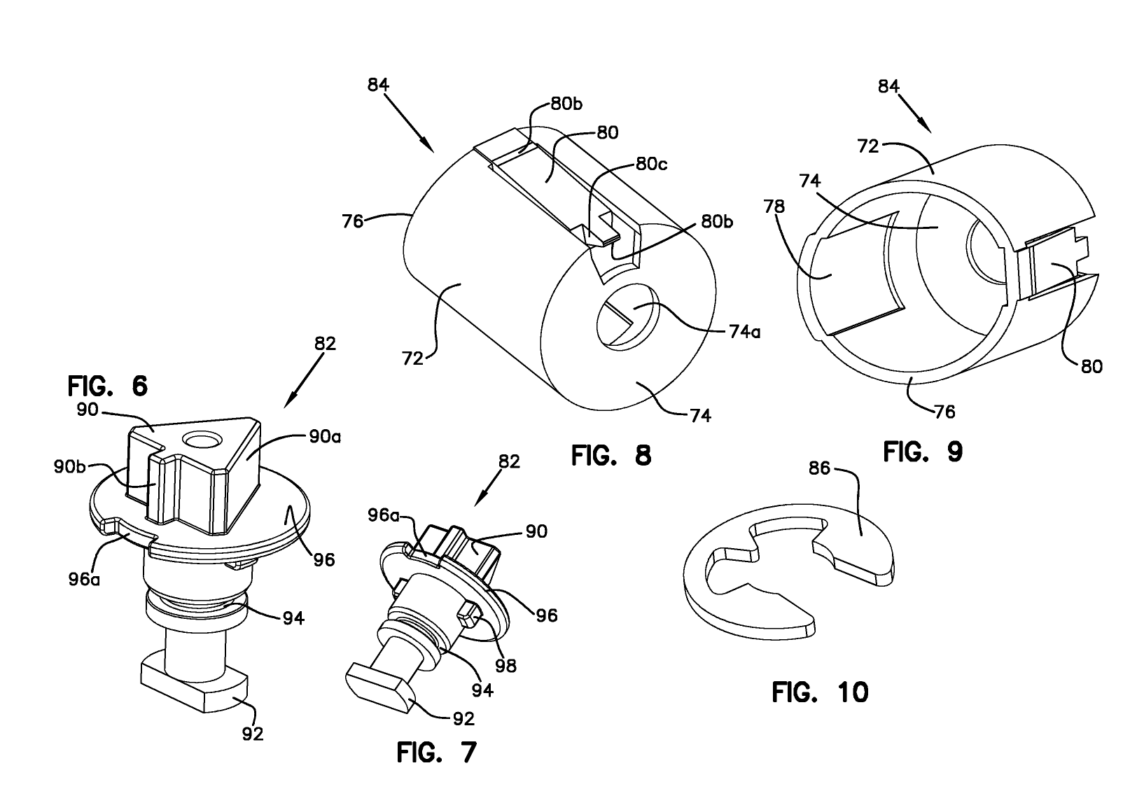

As most easily seen at FIGS. 6 and 7, the lock core 82 can be formed as an integral component having a main body 88 including the key engagement feature 90 and the lock member 92. These features can also be separable components assembled together. As shown, the key engagement feature 90 is configured as a protrusion 90a having a generally triangular prism shape with a further indexing protrusion 90b extending from one of the sides of protrusion 90a. As can be seen at FIG. 3, the key lock engagement structure 66 has a corresponding recessed shape. Many other complementary shapes are possible without departing from the concepts herein. The protrusion 90b and corresponding recessed feature on the key 60 provide an indexing feature such that the key 60 can only engage with the lock assembly in a single orientation. It is noted that the key 60 could be provided with a lock engagement structure 66 that is formed as a protrusion and the core 82 could be provided with a key engagement feature 90 that is formed as a recess without departing from the concepts presented herein. Additionally, the key engagement feature 90 could be provided with a non-symmetrical shape to provide for proper indexing for the key 60.

The main body 88 of the lock core 82 can also be provided with additional features. One such feature is a groove 94 for receiving retainer 86. Another feature is a pair of stand-offs 98 which engage with the stop grooves 50 to provide rotational stop positions for the lock core 82 at the fully locked position and the fully unlocked position. Another feature is a generally disk-shaped base structure 96 formed at the base of the key engagement feature 90. The base structure 96 can be configured to perform at least two functions. First, the base structure 96 can act as an axial stop for the key 60 during insertion. Second, the base structure 96 can interact with the cap 84 to prevent the core 82 from rotating unless a corresponding feature 80 on the cap 84 is moved to a disengaged position, as discussed in more detail later. To facilitate this latter function, the base structure 96 can be provided with a notch 96a, which can alternatively be provided as a protrusion.

Referring to FIGS. 8-9, the cap 84 is shown in greater detail. In one aspect, the cap 84 is integrally formed with a generally cylindrical sidewall 72 adjoining an end wall 74 having a central aperture 74a and having an opposite open end 76. In one aspect, the cap 84 is inserted over the exterior side 48b of the sidewall 48 of the lock shaft feature 46. To ensure that the cap 84 is properly oriented and installed onto the lock shaft feature 46, and thus ensuring that the lock assembly 70 is properly oriented with respect to the base 20, the cap sidewall 72 may be provided with a recessed indexing feature 78 that cooperatively engages with a corresponding protruding feature 47 on the lock shaft feature 46.

The cap 84 may also be provided with a lock clip 80 configured to engage with the notch 96a of the base structure 96. As shown, the lock clip 80 is an integrally formed component of the cap 84. In one aspect, the lock clip 80 has a first end 80a connected to the cap sidewall 72 and a second, free end 80b. The sidewall 48 of the lock shaft feature 46 can include a notch 48d for allowing the ramped engagement surface 80c to extend into the interior side 48a of the lock shaft feature 46.

In one aspect, the second end 80b of the lock clip 80 is configured with a ramped engagement surface 80c. The ramped engagement surface 80c is for engaging with a lock activation feature 26 on the base 20 when the cover 40 is closed relative to the base 20. In the embodiment shown, the lock activation feature 26 is formed as a post structure 26 integrally molded into the base 20. In a relaxed state, when the cover 40 is sufficiently open with respect to the base 20, the second end 80b of the lock clip 80 is engaged with the notch 96a of the base structure 96 to prevent rotation of the core 82. When the cover 40 is moved to the closed position with respect to the base 20, the lock activation feature 26 engages with the ramped engagement surface 80c to deflect the second end 80b such that the second end 80b becomes disengaged from the notch 96a of the base structure 96. Thus, the lock core 82 is free to rotate from the unlocked position to the locked position when the cover 40 is in the closed position. As configured, the notch 96a and lock clip 80 are configured such that the lock assembly 70 is in the unlocked position when the lock clip 80 is engaged with the notch 96a. Accordingly, the lock assembly 70 cannot be moved into the locked position unless the lock clip 80 is disengaged from the notch 96a by fully closing the cover (40).

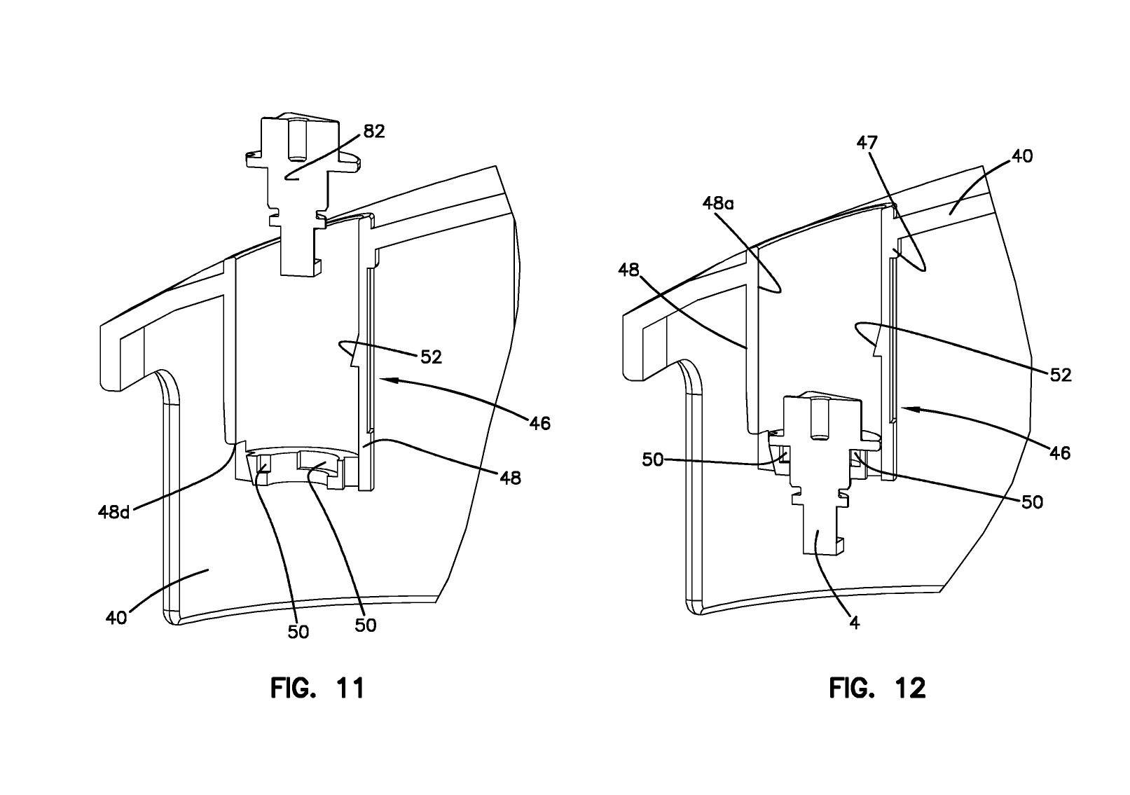

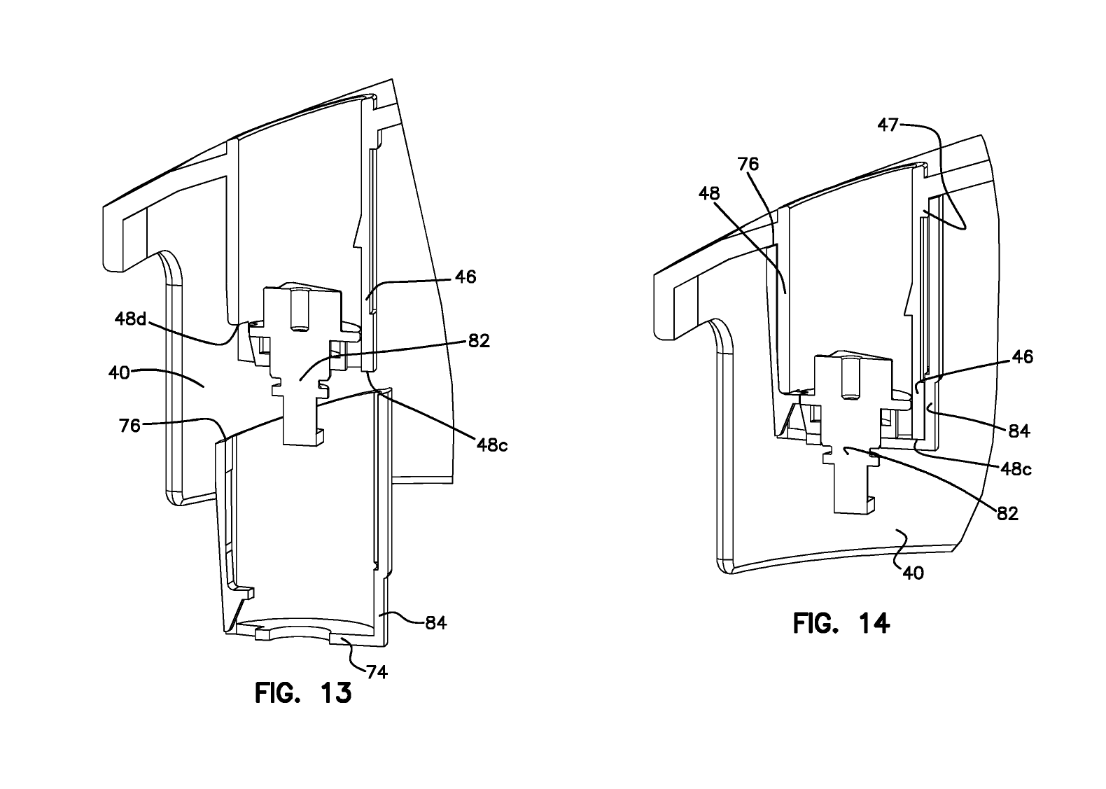

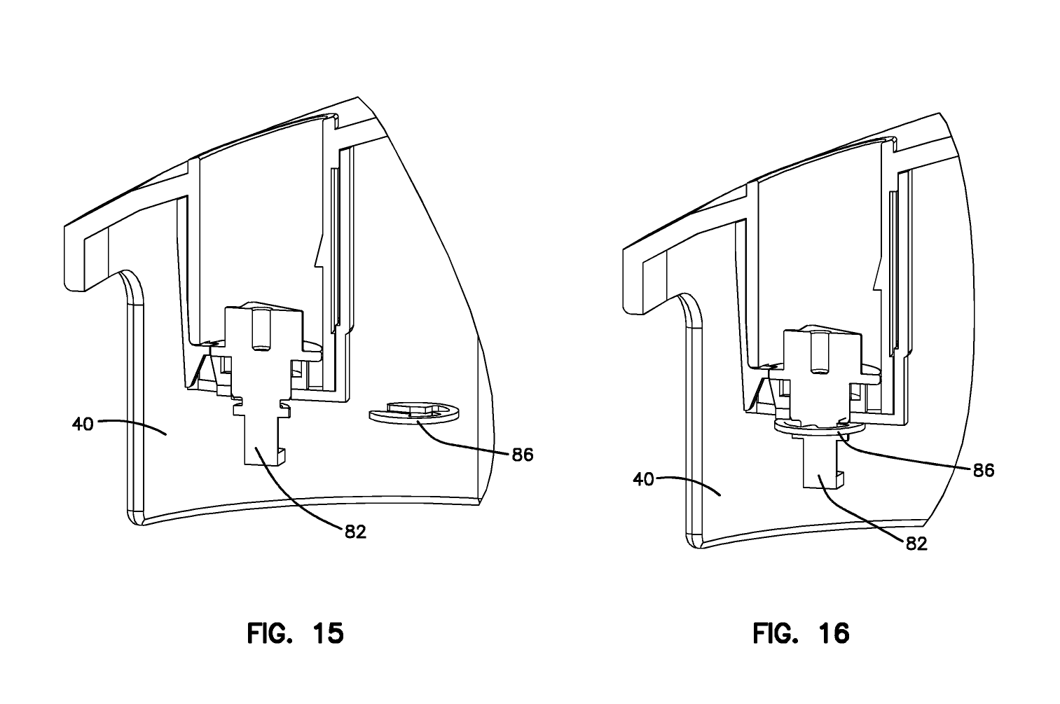

Referring to FIGS. 11-16, the assembly of the lock assembly 70 onto the cover 40 is illustrated. FIG. 11 shows the lock core 82 aligned with the open end 48c of the lock shaft feature 46. FIG. 12 shows the lock core 82 fully inserted into the lock shaft feature 46 such that the stand-offs 98 are received within the stop grooves 50 and such that the base structure 96 rests against the end 48c of the lock shaft feature 46. FIG. 13 shows the cap 84 aligned with the lock shaft feature 46 while FIG. 14 shows the cap 84 fully inserted over the lock shaft feature 46 such that the cap end wall 74 is adjacent to and abutting the open end 48c of the lock shaft feature 46. FIG. 15 shows the retainer 86 aligned with the groove 94 on the lock core 82 while FIG. 16 shows the completed assembly with the retainer 86 inserted into the groove 94. The retainer 86 and the base structure 96 cooperate to retain the lock core 82 and the cap 84 onto the lock shaft feature 46.

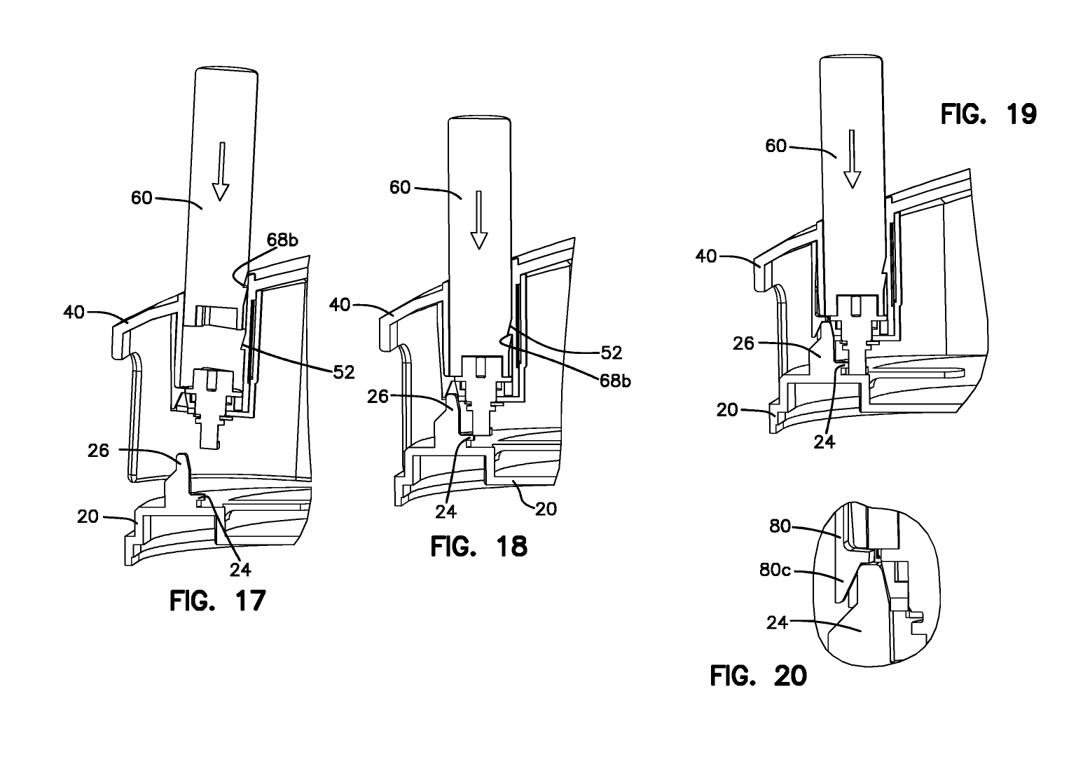

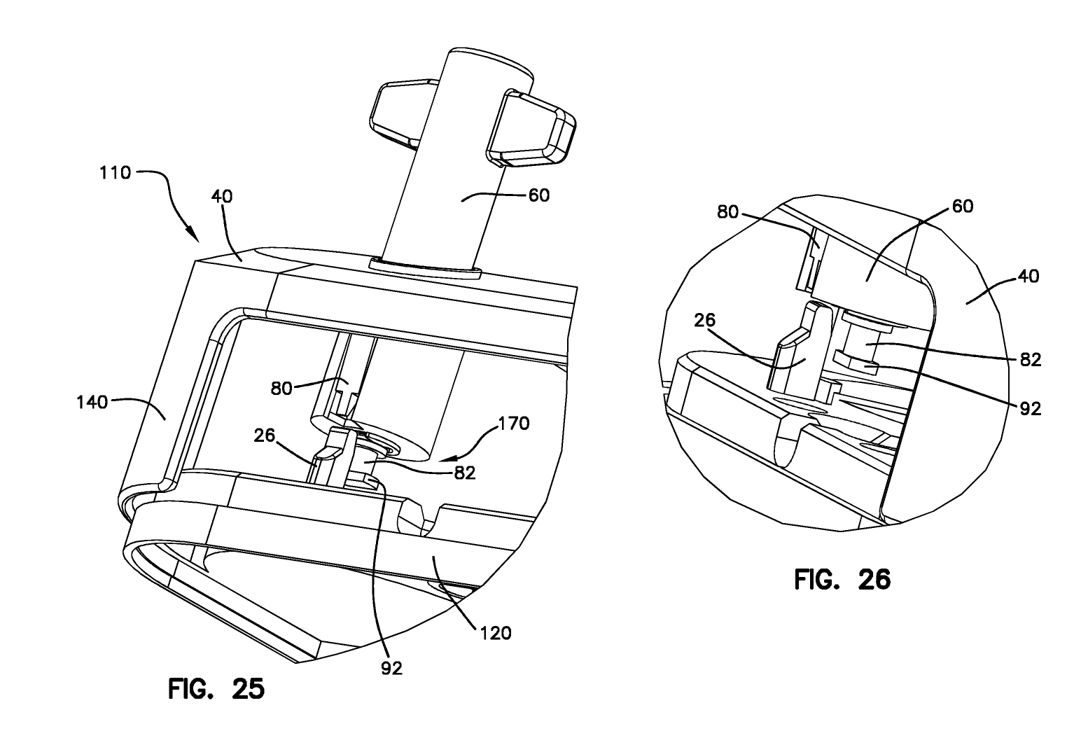

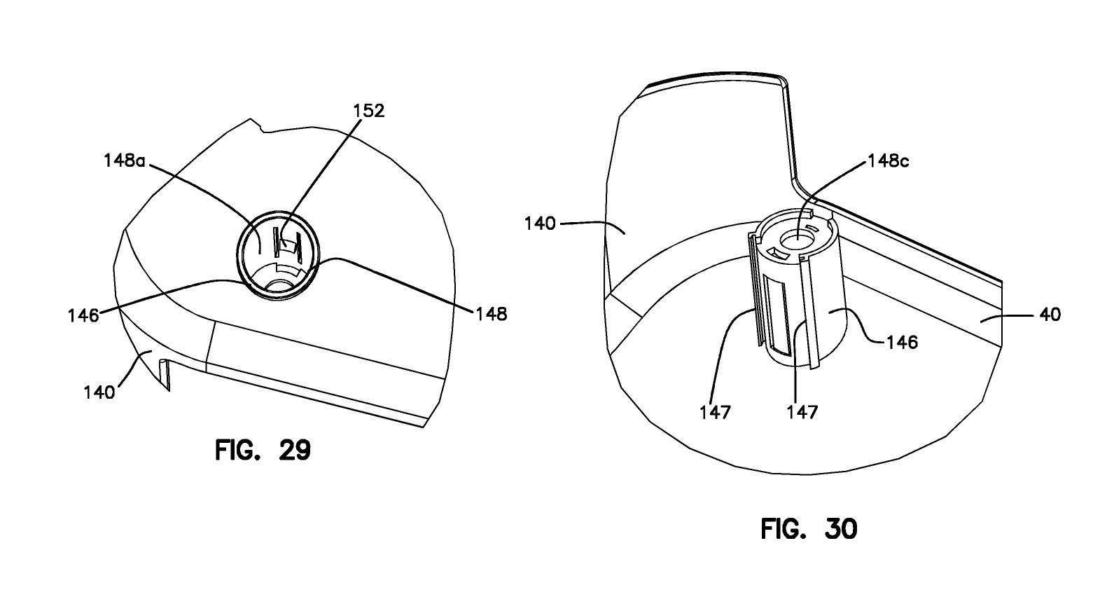

FIGS. 17-28 further illustrate the operation of the lock assembly 70 with respect to the base 20 and cover 40. FIG. 17 shows the key 60 being inserted into the lock shaft feature 46, after initial assembly of the lock assembly 70, with the cover 40 in an open position such that the lock clip 80 is engaged with the base structure notch 96a. FIG. 18 shows the key 60 further inserted such that the cover engagement structure second portion 68b is engaged with the key engagement feature 52. In the embodiment shown, the key engagement feature 52 is deflectable such that the cover engagement structure first portion 68a need not be initially aligned with the key engagement feature 52 when inserting the key 60 into the lock shaft feature 46. Thus, the key 60 can be inserted into the lock shaft feature 56 in any rotational position. When the first portion 68a is not aligned with feature 52, an audible click will be produced once the key 60 once the key 60 is rotated such that the engagement feature 52 snaps into the cover engagement structure second portion 68b. Once in the key 60 is in this position, and as long as the cover 40 is not fully closed, the key 60 cannot be removed or turned due to the lock clip 80 being engaged with the notch 96a. FIGS. 25 and 26 further illustrate the interaction between the lock activation feature 26 and the lock clip 80 in this state.

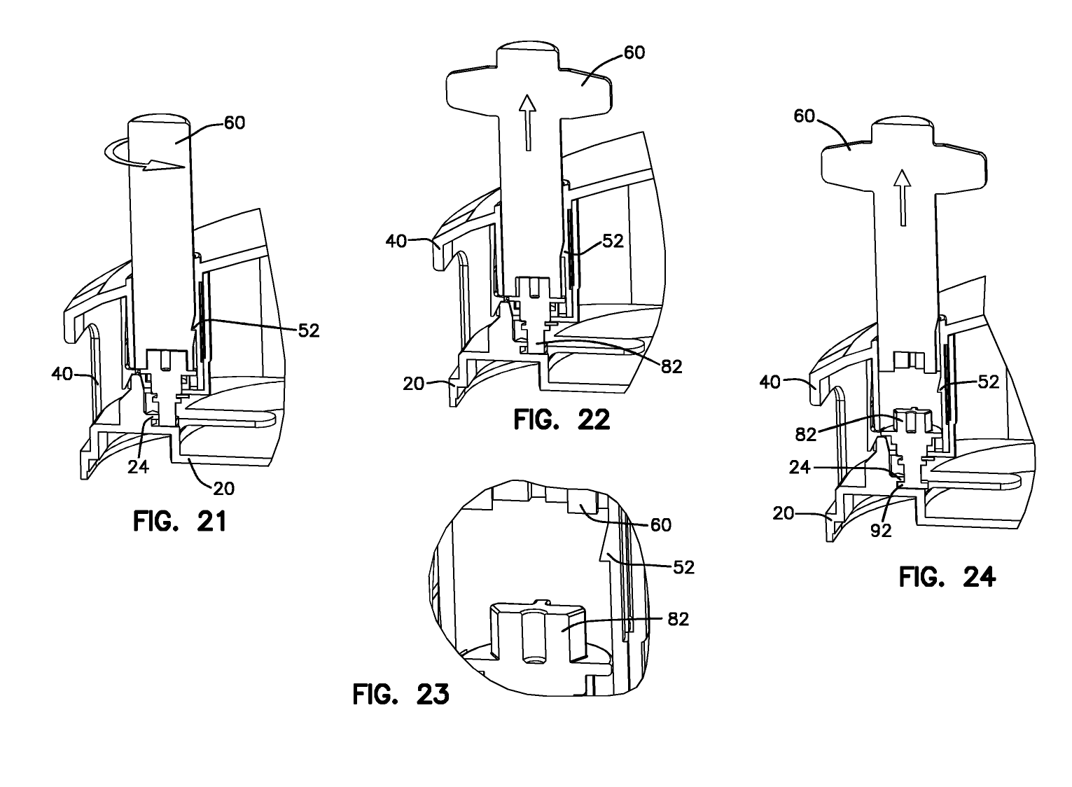

FIGS. 19 and 20 show the cover 40 in a fully closed position relative to the base 20 such that the lock activation feature 26 has engaged the ramped surface 80c to disengage the lock clip 80 from the base structure 96. At this point, the key 60 can now be turned to operate the lock core 82, as shown in FIG. 21. FIG. 22 shows the key 60 having been turned such that the lock assembly 70 is in the locked position such that the cover 40 is now secured to the base 20. At this point, the cover engagement structure first portion 68a is aligned with key engagement feature 52 to allow the key 60 to be removed from the lock shaft feature 46, as shown in FIGS. 23 and 24.

The above described combination of features results in a telecommunications enclosure 10 in which the key 60 can only operate the lock assembly 70 to a locked position when the cover 40 is fully closed and in which the key 60 can only be removed from the cover 40 when the lock assembly 70 is in the locked position. This operation prevents an operator from removing the key 60 when the cover 40 may not be fully closed and/or is unlocked and ensures that the cover 40 is fully closed and locked to the base 20 before removal of the key 60 is allowed.

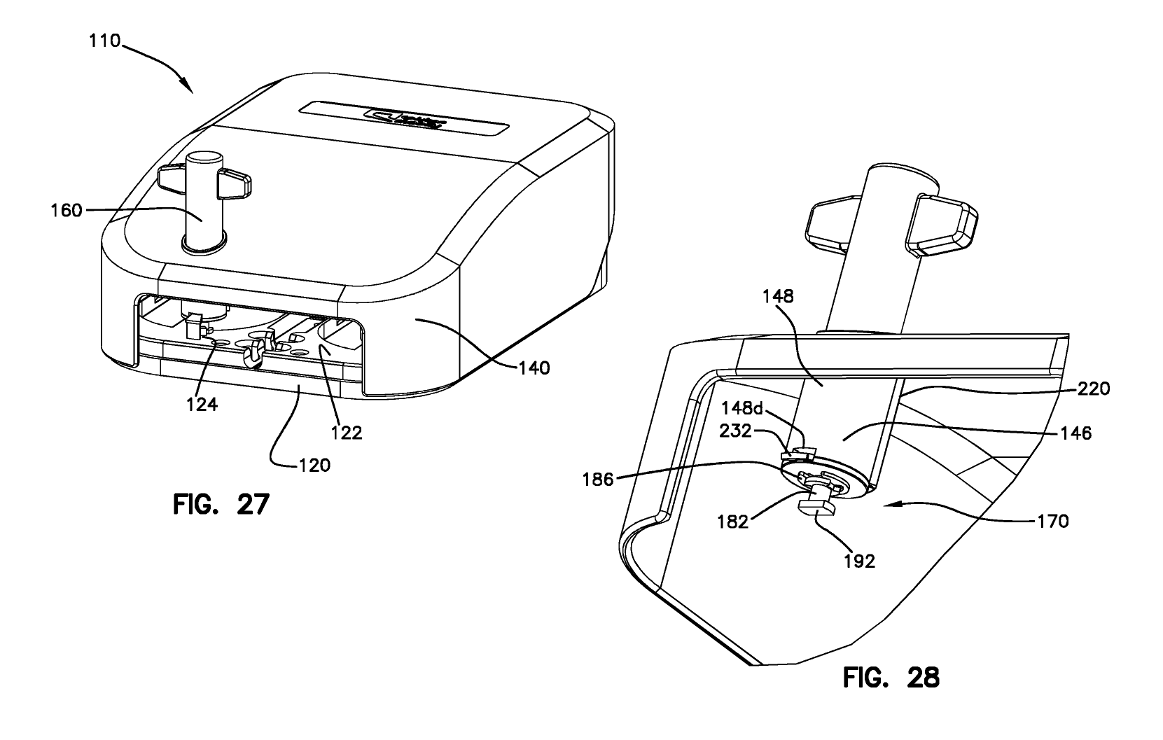

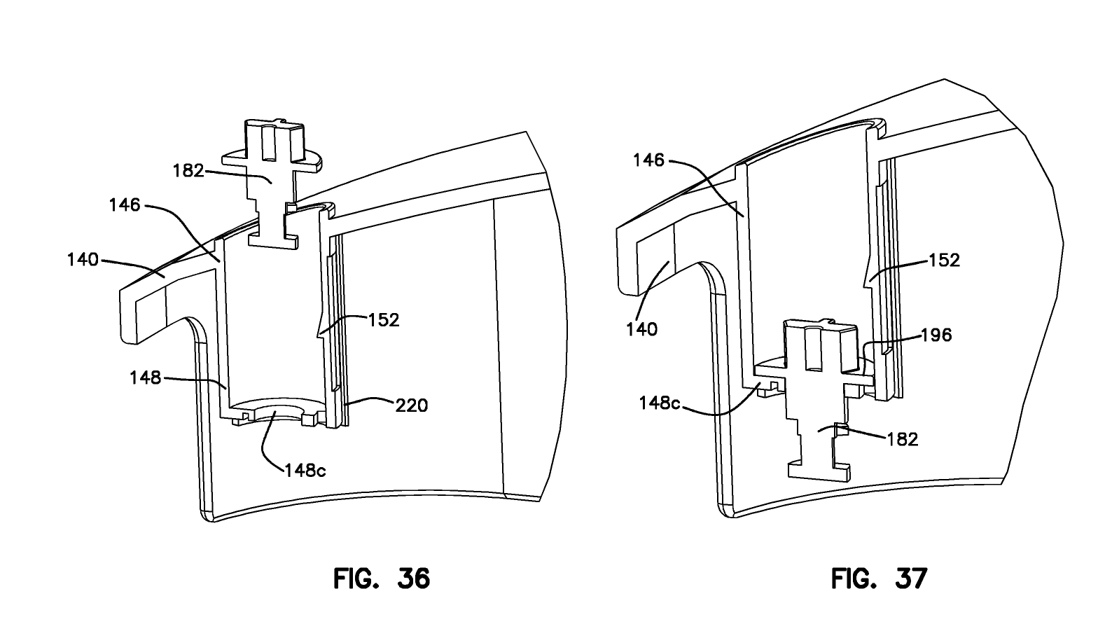

Referring to FIGS. 27-52, a second embodiment of a telecommunications enclosure 110 is shown. Where like or similar features or elements are shown, corresponding or like reference numbers will be used where possible (e.g. 110 instead of 10). Many of the concepts and features of the second embodiment are similar to the first embodiment shown in FIGS. 1-26. As such, the description for the first embodiment is applicable for the second embodiment. The description for the second embodiment will be limited to the differences between the first and second embodiments. The primary difference between the embodiments is the configuration of the lock assembly.

As with the first embodiment, the telecommunications enclosure 110 includes a cover 140, a base 120, and a lock assembly 170 mounted to the cover 140. The key 60 of the first embodiment 10 is usable with the second embodiment 110 and therefore does not require any additional discussion here. Also, the base 120 is of substantially similar construction as the base 20.

However, the lock shaft feature 146 of the cover 140 is slightly modified to accommodate the differently configured lock assembly 170. For example, the lock shaft feature 146 is notched to accommodate a lock clip 232 and also includes a pair of channels 147 that engage with the sides 234 of the cap 220 of the lock assembly 170 secure the cap 220 to retain the lock shaft feature 146. The cap 220 is further aligned and secured to the lock shaft feature 146 via a protrusion 228 on the cap which inserts into correspondingly shaped aperture 149 in the lock shaft feature 146. The lock core 182 is also slightly modified in relation to the first embodiment. For example, the stand-offs 98 and notch 96a are not provided. Instead, the core 182 is additionally provided with a projection arrangement 206 disposed about an aperture 208 that interlocks with a corresponding projection arrangement 204 on a rotation disk 200 of the lock assembly 170. The projection arrangements 204, 206 operate to rotationally fix the rotation disk 200 to the lock core 182.

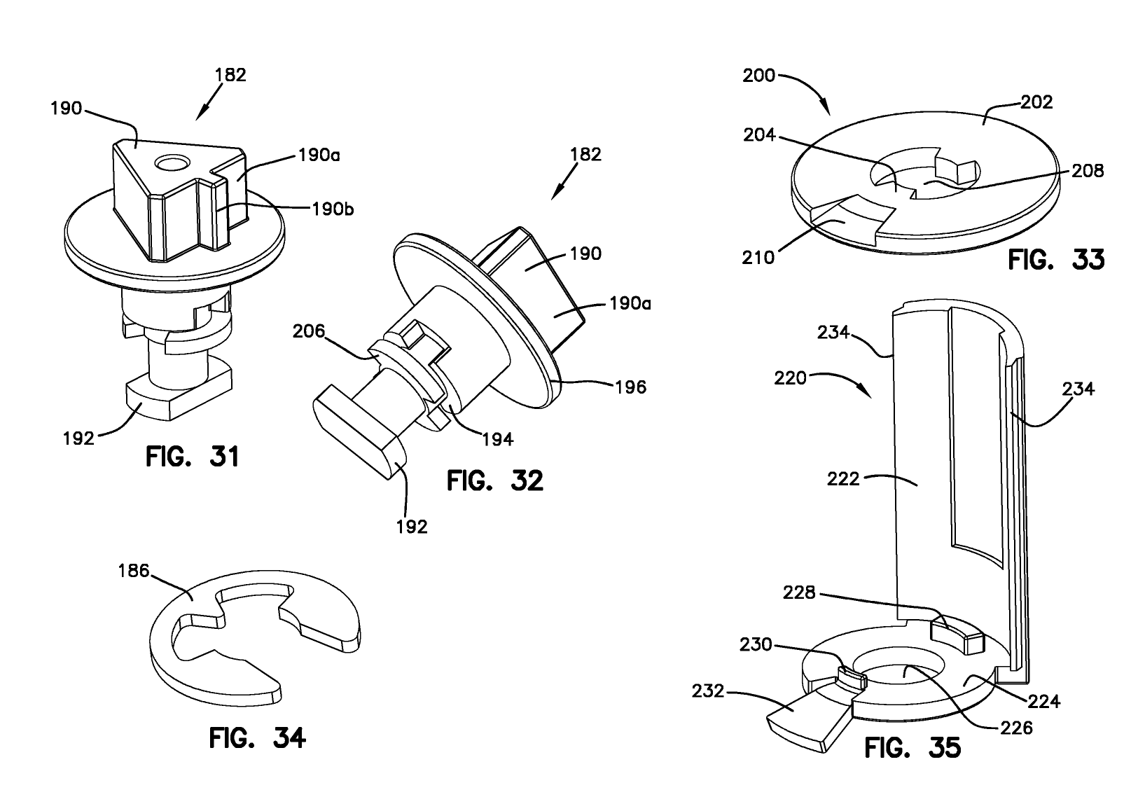

As most easily seen at FIGS. 31-35, the lock assembly 170 has several additional features. Most notably, the lock assembly 170 relies upon a different structure to enable and disable the operation of the lock assembly 170 when the cover 140 is in the open position. Specifically, the lock assembly 170 includes the previously mentioned rotation disk 200 and cap 220 which interact to perform this function. The cap 220 includes a sidewall portion 222 connected to an end portion 224 having an aperture 226 and a projection 230. The rotation disk 200 is provided with a notch 210 into which the projection 230 can be selectively engaged and disengaged by operation of a clip 232 connected to the end portion 224. Similar to the clip 80 of the first embodiment, the clip 232 engages with the lock activation feature 126 provided on the base 120. Accordingly, the lock assembly 170 is prevented from moving out of the unlocked position when the projection 230 is engaged with the notch 210, which is the case when the cover 140 is not in the closed position (i.e. the cover 140 is in an at a least partially open position). Likewise, the operation of the lock assembly 170 is enabled when the cover 140 is closed and the lock activation feature 126 deflects the clip 232 upwards such that the projection 230 becomes disengaged from the notch 210.

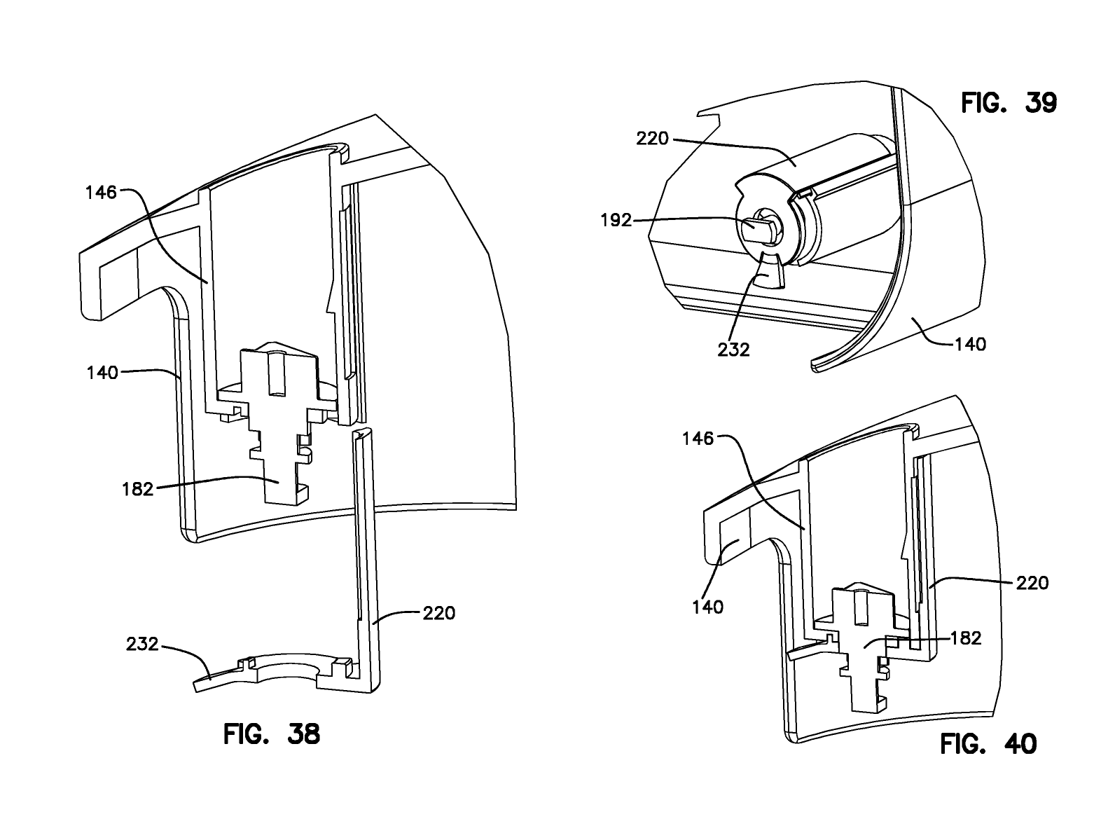

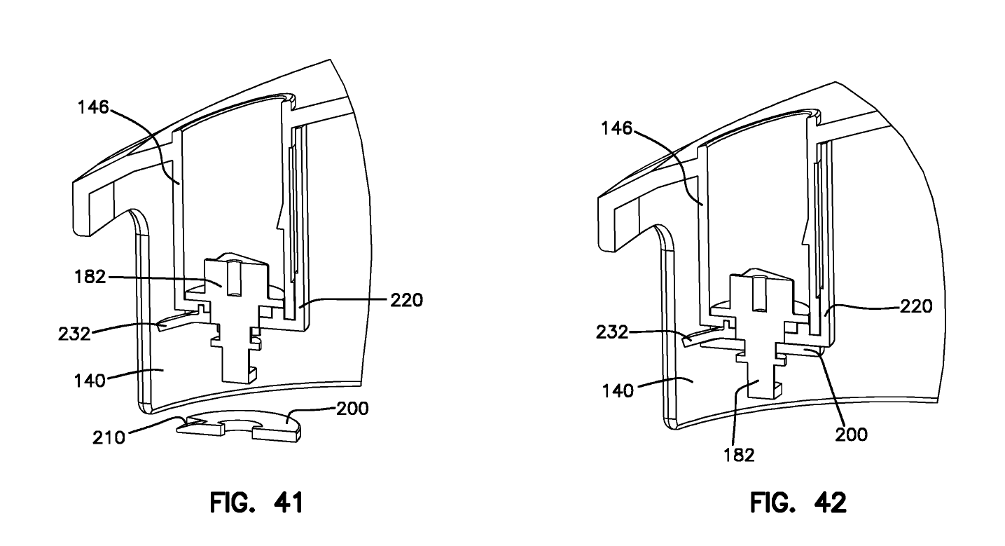

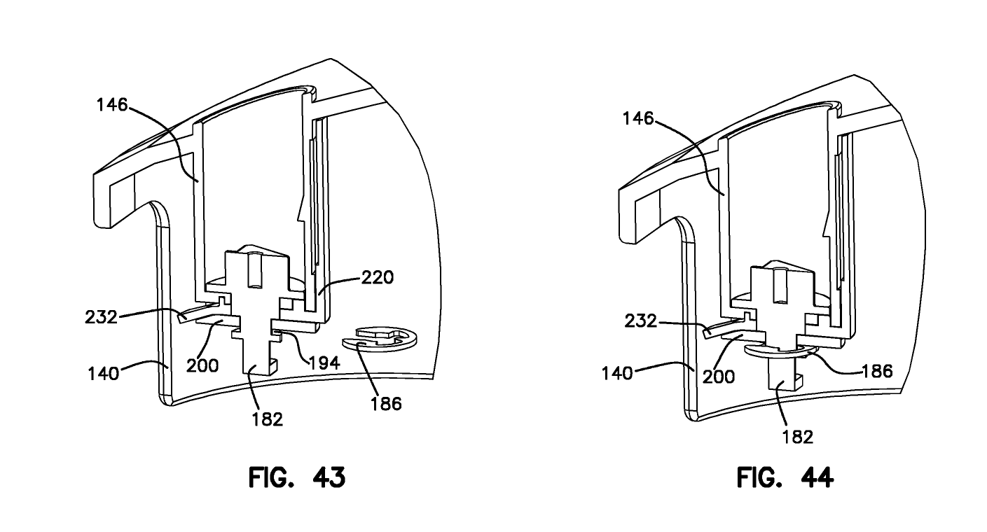

Referring to FIGS. 36-44, the assembly of the lock assembly 170 onto the cover 140 is illustrated. FIG. 36 shows the lock core 182 aligned with the opening 148c of the lock shaft feature 146. FIG. 37 shows the lock core 182 fully inserted into the lock shaft feature 146 such that the base structure 196 rests against the end 148c of the lock shaft feature 46. FIG. 38 shows the cap 220 aligned with the lock shaft feature 146 while FIGS. 39-40 shows the cap 220 fully inserted over the lock shaft feature 146 such that the projection 228 extends into the aperture 149 and such that the sides 234 are inserted into channels 147. FIGS. 41 and 42 respectively show alignment and insertion of the rotation disk 200 onto the lock core 182. FIG. 43 shows the retainer 186 aligned with the groove 194 on the lock core 182 while FIG. 44 shows the completed assembly with the retainer 186 inserted into the groove 194. The retainer 186 and the base structure 196 cooperate to retain the lock core 182, the rotation disk 200 and the cap 220 onto the lock shaft feature 146.

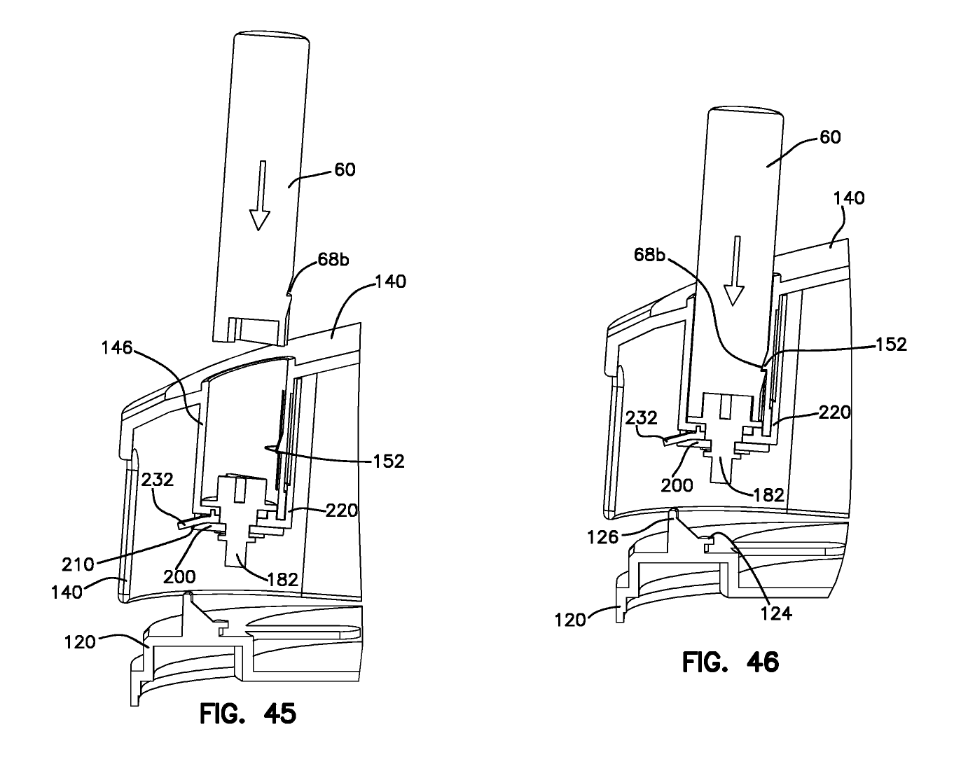

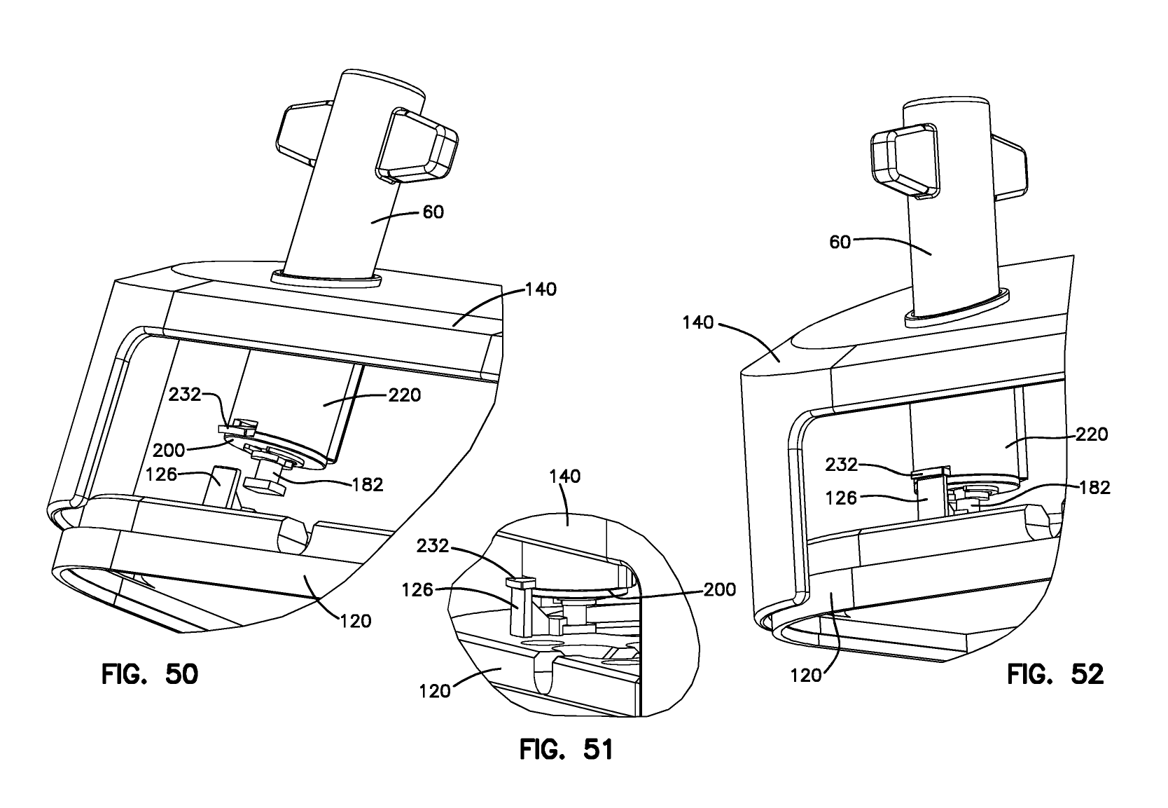

FIGS. 45-52 further illustrate the operation of the lock assembly 170 with respect to the base 120 and cover 140. FIG. 45 shows the key 60 being inserted into the lock shaft feature 146 with the cover 140 in an open position wherein the projection 230 is engaged within the notch 210. FIG. 46 shows the key 60 further inserted such that the cover engagement structure second portion 68b is engaged with the key engagement feature 152. Once the key 60 is in this position, and as long as the cover 140 is not fully closed, the key 60 cannot be removed or turned due to the projection 230 being engaged with the notch 210, as shown in FIG. 50.

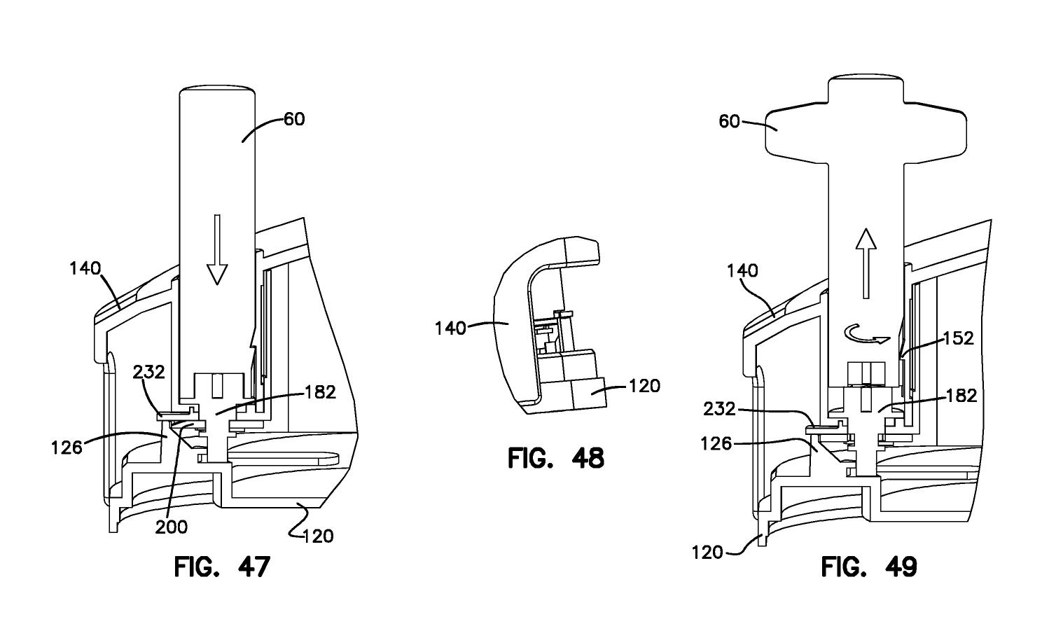

FIGS. 47-49 show the cover 140 in a fully closed position relative to the base 120 such that the lock activation feature 126 has engaged the projection 232 to lift and disengage the projection 232 from the notch 210. FIGS. 51-52 further illustrate this action. At this point, the key 60 can now be turned to operate the lock core 182. FIG. 49 shows the key 60 having been turned such that the lock assembly 170 is in the locked position such that the cover 140 is now secured to the base 120. At this point, the cover engagement structure first portion 68a is aligned with key engagement feature 152 to allow the key 60 to be removed from the lock shaft feature 146, as shown in FIG. 49.

While this invention has been particularly shown and described with references to preferred embodiments thereof, it will be understood by those skilled in the art that various changes in form and details may be made therein without departing from the scope of the invention encompassed by the appended claims. The drawings are not necessarily to scale, emphasis instead being placed upon illustrating the principles of the invention and other modifications within the scope. Any such modifications or variations that fall within the purview of this description are intended to be included therein as well. It is understood that the description herein is intended to be illustrative only and is not intended to be limitative.

### PARTS LIST

10 telecommunications enclosure
12 interior volume
20 base
22 mounting surface
24 lock engagement feature
26 lock activation feature
40 cover
42 cover surface
44 sidewalls
46 lock shaft feature
47 indexing feature
48 sidewall
48a interior side
48b exterior side
48c open end
48d notch
50 stop grooves
52 key engagement structure
60 key
62 post
62a first end
62b second end
64 handle
64a first handle portion
64b second handle portion
66 lock engagement structure
68 cover engagement structure
68a first portion
68b second portion
70 lock assembly
72 cap sidewall
74 cap end wall
74 cap aperture
76 cap open end
78 indexing feature
80 lock clip
80a first end
80b second end
80c ramped engagement surface
82 core
84 cap
86 retainer
88 core main body
90 key engagement structure
90a triangular protrusion
90b protrusion
92 lock member
94 groove
96 base structure
96a notch
98 stand-offs
110 telecommunications enclosure
112 interior volume
120 base
122 mounting surface
124 lock engagement feature
126 lock activation feature
140 cover
142 cover surface
144 sidewalls
146 lock shaft feature
147 channels
148 sidewall
148a interior side
148b exterior side
148c opening
148d notch
149 aperture
150 stop grooves
152 key engagement structure
170 lock assembly
182 core
185 rotation disk
186 retainer
188 core main body
190 key engagement structure
190a triangular protrusion
190b protrusion
192 lock member
194 groove
196 base structure
200 cover disk
202 cover disk main body
204 cover disk projection arrangement
206 lock core projection arrangement
208 rotation disk aperture
210 rotation disk notch
220 cap
222 cap sidewall portion
224 cap end portion
226 cap end portion aperture
228 cap protrusion
230 lock protrusion
232 clip

1. A telecommunications enclosure comprising:
a. a base including a lock engagement feature and a lock activation feature;
b. a cover including a key engagement feature, the cover being movable between open and closed positions relative to the base;
c. a lock assembly including a lock member for locking the cover to the base via engagement with the lock engagement feature and including a lock clip for enabling and disabling operation of the lock assembly;
d. a key including a cover engagement structure;
e. the lock clip being engaged with the lock activation feature when the cover is in the closed position to enable operation of the lock assembly;
f. the lock clip disabling operation of the lock assembly when the cover is in the open position such that the lock assembly is prevented from being operated out of the open position; and
g. the key engagement feature engaging with the cover engagement structure to secure the key to the cover when the key operates the lock assembly out of the locked position.

2. The telecommunications enclosure of claim 1, wherein:
a. the lock activation feature is a post structure integrally molded with the base.

3. The telecommunications enclosure of claim 1, wherein:
a. the lock assembly includes a lock core having at least one lock member for rotatable engagement with the lock engagement feature of the base.

4. The telecommunications enclosure of claim 3, wherein:
a. the lock core includes a key engagement feature at an end opposite the location of the at least one lock member.

5. The telecommunications enclosure of claim 4, wherein:
a. the cover defines a generally cylindrical lock shaft feature onto which the lock assembly is mounted.

6. The telecommunications enclosure of claim 1, wherein:
a. the key is insertable into the lock shaft feature of the cover to engage with the lock engagement feature of the lock assembly in either the unlocked position or the locked position.

7. The telecommunications enclosure of claim 6, wherein:
a. the key engagement feature is formed as a portion of the lock shaft feature and is deflectable relative to the lock shaft feature.

8. The telecommunications enclosure of claim 5, further comprising:
a. a cap mounted to the lock shaft feature, wherein the lock clip is formed as a portion of the cap.

9. The telecommunications enclosure of claim 8, wherein:
a. lock core further includes a base having a notch for receiving the lock clip.

10. The telecommunications enclosure of claim 8, wherein:
a. the lock assembly further includes a rotation disk having a notch for receiving the lock clip.

11. A telecommunications enclosure comprising:
a. a base including a lock engagement feature and a lock activation feature;
b. a cover including a key engagement feature, the cover being movable between open and closed positions relative to the base;
c. a lock assembly including a lock core having a base member and a lock member for locking the cover to the base via engagement with the lock engagement feature and including a lock clip for enabling and disabling operation of the lock assembly;
d. a key including a cover engagement structure;
e. the lock clip enabling operation of the lock assembly when the cover is in the closed position, the lock clip being engaged with the lock activation feature and disengaged with a notch on the lock core base member when the cover is in the closed position;
f. the lock clip disabling operation of the lock assembly, when the cover is in the open position, the lock clip engaging with the lock core base member notch such that the lock assembly is prevented from being operated out of the open position; and
g. the key engagement feature engaging with the cover engagement structure to secure the key to the cover when the key operates the lock assembly out of the locked position.

12. A telecommunications enclosure comprising:
a. a base including a lock engagement feature and a lock activation feature;
b. a cover including a key engagement feature, the cover being movable between open and closed positions relative to the base;
c. a lock assembly including a lock core having a lock member for locking the cover to the base via engagement with the lock engagement feature and including a rotation disk secured to the lock core and a lock clip for enabling and disabling operation of the lock assembly;
d. a key including a cover engagement structure;
e. the lock clip enabling operation of the lock assembly when the cover is in the closed position, the lock clip being engaged with the lock activation feature and disengaged with a notch on the rotation disk when the cover is in the closed position;
f. the lock clip disabling operation of the lock assembly, when the cover is in the open position, the lock clip engaging with the rotation disk notch such that the lock assembly is prevented from being operated out of the open position; and
g. the key engagement feature engaging with the cover engagement structure to secure the key to the cover when the key operates the lock assembly out of the locked position.

13. A method for servicing a telecommunications enclosure, the method including the steps of:
a. providing a telecommunications enclosure having a base and a cover that can be secured together with a lock assembly operable by a key;
b. axially inserting the key into the lock assembly;
c. rotating the key to axially engage the key to the cover and to rotate a lock member to an unlocked position such that the cover can be opened with respect to the base; and
d. disabling the operation of the lock assembly such that the lock assembly cannot be moved out of the unlocked position by opening the cover to axially disengage the lock assembly from a portion of the base.

14. The method for servicing a telecommunications enclosure of claim 13, further including the steps of:
a. enabling the operation of the lock assembly such that the lock assembly can be moved out of the unlocked position by closing the cover such that the lock assembly axially engages with the portion of the base;
b. rotating the key to axially disengage the key from the cover and to rotate the lock member to a locked position such that the cover cannot be opened with respect to the base; and
c. axially removing the key from the lock assembly.
